(19) United States
(12) Patent Application Publication
(10) Pub. No.: US 2008/0083616 A1
(43) Pub. Date: Apr. 10, 2008

(54) Co-Fe-Zr BASED ALLOY SPUTTERING TARGET MATERIAL AND PROCESS FOR PRODUCTION THEREOF

(75) Inventors: Jun Fukuoka, Yasugi-shi (JP); Hiroshi Takashima, Yasugi-shi (JP); Tomonori Ueno, Yasugi-shi (JP); Mitsuharu Fujimoto, Yasugi-shi (JP); Hide Ueno, Yasugi-shi (JP)

Correspondence Address: SUGHRUE MION, PLLC, 2100 PENNSYLVANIA AVENUE, N.W., SUITE 800, WASHINGTON, DC, 20037, US

(73) Assignee: HITACHI METALS, LTD., Tokyo (JP)

(21) Appl. No.: 11/869,462

(22) Filed: Oct. 9, 2007

(30) Foreign Application Priority Data
Oct. 10, 2006 (JP) 2006-276605

(51) Int. Cl. C23C 14/34; B22F 3/12

(52) U.S. Cl. 204/298.13; 419/30

(57) ABSTRACT

The present invention relates to a Co—Fe—Zr based alloy target material for forming a soft magnetic film of the Co—Fe—Zr based alloy used in a perpendicular magnetic recording medium, and provides a Co—Fe—Zr based alloy target material having a low magnetic permeability and good sputtering characteristics and a process for producing this target material. A Co—Fe—Zr based alloy sputtering target material represented by the compositional formula based on the atomic ratio: (Coₓ—Fe_{100-X})_{100-(Y+Z)}—Zr_{Y}-M_{Z} (20≦X≦70, 2≦Y≦15 and 2≦Z≦10) in which the element(s) M is one or more elements selected from the group consisting of Ti, V, Nb, Ta, Cr, Mo, W, Si, Al and Mg, wherein a phase composed of HCP-Co and an alloy phase composed mainly of Fe are finely dispersed in the microstructure of the target material.

### BACKGROUND OF THE INVENTION

The present invention relates to a Co—Fe—Zr based alloy sputtering target material for forming a soft magnetic film and a process for producing the target material.

In recent years, magnetic recording techniques have been markedly advanced and the improvement of the density of magnetic recording media have been vigorously investigated in order to reduce the size of a drive and increase the capacity. However, when an attempt is made to realize the drive size reduction and the recording density improvement at the same time in a recording medium adopting a longitudinal magnetic recording method which has been spread far and wide, a region used for recording of 1 bit is decreased, so that the domain concerned loses its magnetic force owing to offset by the magnetic force of the surrounding domains. Therefore, a perpendicular magnetic recording method was developed as a method for realizing further improvement of the recording density and has been put to practical use.

In the perpendicular magnetic recording method, the magnetic film of a perpendicular magnetic recording medium is formed so that the axis of easy magnetization may be perpendicular to the medium surface, and even if the recording density is increased, the diamagnetic field in a bit is small and the deterioration of record-regenerating characteristics is slight. Thus, this method is suitable for improving the recording density. In general, the perpendicular magnetic recording medium has a multi-layer structure composed of substrate/soft magnetic under layer/Ru intermediate layer/CoPtCr—SiO₂ magnetic layer/protective layer (see, for example, non-patent document 1).

Since the soft magnetic under layer of the perpendicular magnetic recording medium is required to have excellent soft magnetic characteristics, an amorphous soft magnetic alloy is used therein. As typical amorphous alloys for the soft magnetic under layer, Fe—Co—B alloy films (see, for example, patent document 1), Co—Zr—Nb alloy films (see, for example, non-patent document 2) and the like have already been put to practical use. However, the following problems in these alloy films are pointed out: the Fe—Co—B alloy films are poor in corrosion resistance and the Co—Zr—Nb alloy films have a low saturation magnetic flux density.

Therefore, in particular, Co—Fe—Zr based alloy films have recently been considered hopeful as a substitute for the above-exemplified alloy films.

In general, a magnetron sputtering method is adopted for depositing the soft magnetic under layer. The magnetron sputtering method is as follows: a permanent magnet is located on the back of a base material called a target material, a magnetic flux is passed through onto the surface of the target material, and plasma is converged on the pass-through-flux region to make it possible to deposit thin film at a high speed. Since the magnetron sputtering method is characterized by the passing-through of a magnetic flux onto the surface of the target material, it becomes difficult to obtain a pass-through-flux necessary for converging plasma on the sputtering surface of the target material, when the magnetic permeability of the target material itself is high. Accordingly, it is desirable to reduce the magnetic permeability of the target material itself as much as possible.

However, in the magnetron sputtering method, an erosion area is centered at a portion at which plasma is converged, so that the target material has to be replaced when only partly consumed. In particular, a target material composed of a ferromagnetic material such as a Co—Fe—Zr based alloy involves the following problem: a large portion of a magnetic flux generated by a magnet set on the back of the target material intrudes into the target material, and only a slight magnetic flux is generated on the surface of the target material, so that the target material is locally and deeply consumed, resulting in an extremely short life of the target material. Particularly in depositing the soft magnetic under layer of the above-mentioned perpendicular magnetic recording medium which has an extremely large thickness of 150 to 200 nm, the extremely short life of the target material is a serious problem, and the following conflicting requirements have to be satisfied: a sufficient pass-through-flux is obtained while setting the thickness of the target material at as large a thickness as possible in order to reduce the frequency of replacement of the target material.

The present inventors have disclosed an example of the reduction of the magnetic permeability of the target material on the basis of the above background. That is, the present inventors have disclosed that when a boride phase present as a second phase is finely and uniformly dispersed in the metal structure of a Fe—Co—B based alloy target material, a low magnetic permeability can be imparted to the target material (see patent document 2).

Patent document 1: JP-A-2004-030740

Patent document 2: JP-A-2004-346423

Non-patent document 1: Shunji Takenoiri et al., Fuji Electric Journal Vol. 77, No. 2, 2004, p. 121

Non-patent document 2: D. H. Hong, S. H. Park and T. D. Lee, “Effects of CoZrNb Surface Morphology on Magnetic Properties and Grain Isolation of CoCrPt Perpendicular Recording Media”, IEEE Trans. Magn., Vol. 41, No. 10, p. 3148-3150, October, 2005

### SUMMARY OF THE INVENTION

In general, the above-mentioned Co—Fe—Zr based alloy target material is produced by a melt casting method. However, the following problem has been pointed out: the magnetic permeability of the target material is so high that no sufficient pass-through-flux can be obtained.

An object of the present invention is to provide a Co—Fe—Zr based alloy target material having a low magnetic permeability and a high use efficiency which can give a strong pass-through-flux, and a process for producing said target material.

The present inventors conducted various researches in order to reduce the magnetic permeability of a Co—Fe—Zr based alloy sputtering target material, and consequently found that when a structure obtained by dispersing a phase consisting of HCP-Co and a phase consisting of an alloy composed mainly of Fe is used as the structure of the Co—Fe—Zr based alloy sputtering target material, the magnetic permeability of the target material can be reduced and a strong pass-through-flux can be obtained. Thus, the present invention has been accomplished.

That is, the present invention provides a Co—Fe—Zr based alloy sputtering target material represented by the compositional formula based on the atomic ratio: (Coₓ—Fe_{100-X})_{100-(Y+Z)}—Zr_{Y}-M_{Z} (20≦X≦70, 2≦Y≦15 and 2≦Z≦10) in which the element(s) M is one or more elements selected from the group consisting of Ti, V, Nb, Ta, Cr, Mo, W, Si, Al and Mg, wherein a phase composed of HCP-Co and an alloy phase composed mainly of Fe are finely dispersed in the microstructure of the target material.

The present invention also provides a Co—Fe—Zr based alloy sputtering target material represented by the compositional formula based on the atomic ratio: (Coₓ—Fe_{100-X})_{100-(Y+Z)}—Zr_{Y}-M_{Z} (20≦X≦70, 2≦Y≦15 and 2≦Z≦10) in which the element(s) M is one or more elements selected from the group consisting of Ti, V, Nb, Ta, Cr, Mo, W, Si, Al and Mg, wherein an alloy phase composed mainly of Fe is finely dispersed in a main phase composed of HCP-Co in the structure of the target material.

The above-mentioned Co—Fe—Zr based alloy sputtering target material can be produced by sintering under pressure mixed powder obtained by mixing Co powder and alloy powder obtained by subjecting Fe, Zr and the element(s) M to alloying treatment.

As the above-mentioned alloy powder, powder obtained by subjecting Fe, Co, Zr and the element(s) M to alloying treatment may also be used.

The above-mentioned alloying treatment is preferably rapid solidification treatment of an alloy melt.

The present invention can provide a Co—Fe—Zr based alloy target material for forming a soft magnetic film which permits stable magnetron sputtering, and hence it is a very effective technique for producing an industrial product which requires a soft magnetic film of the Co—Fe—Zr based alloy, such as a perpendicular magnetic recording medium.

### BRIEF DESCRIPTION OF THE DRAWINGS

FIG. 1 is a scanning electron micrograph of the microstructure of sample 1 in a working example.

FIG. 2 is an X-ray diffraction pattern of sample 1 in the working example.

FIG. 3 is a scanning electron micrograph of the microstructure of sample 4 in the working example.

FIG. 4 is an X-ray diffraction pattern of sample 4 in the working example.

FIG. 5 is a scanning electron micrograph of the microstructure of sample 11 in another working example.

FIG. 6 is an X-ray diffraction pattern of sample 11 in this working example.

FIG. 7 is a scanning electron micrograph of the microstructure of sample 21 in still another working example.

FIG. 8 is an X-ray diffraction pattern of sample 21 in this working example.

FIG. 9 is a scanning electron micrograph of the microstructure of sample 31 in still another working example.

FIG. 10 is an X-ray diffraction pattern of sample 31 in this working example.

FIG. 11 is a scanning electron micrograph of the microstructure of sample 33 in this working example.

FIG. 12 is an X-ray diffraction pattern of sample 33 in this working example.

### DETAILED DESCRIPTION OF THE INVENTION

As described above, the most important characteristic of the present invention is to control the microstructure of a Co—Fe—Zr based alloy target material in order to reduce the magnetic permeability of the target material. That is, the most important characteristic is to control the microstructure of the target material so that a phase composed of HCP-Co and an alloy phase composed mainly of Fe may be finely dispersed in the microstructure.

The reason why the structure of the Co—Fe—Zr based alloy sputtering target material of the present invention is controlled so that the phase composed of HCP-Co and the alloy phase composed mainly of Fe may be finely dispersed in the structure is explained below.

For reducing the magnetic permeability of an alloy with a high content of a ferromagnetic material Co or Fe, a method has been adopted in which a nonmagnetic element is added and then alloyed. In the case of an alloy containing both Fe and Co, a sintered structure has also been investigated in which alloying of Fe and Co with each other is suppressed in order to prevent an increase of magnetic moment caused by the alloying of Fe and Co.

The present inventors tried to adopt the above-mentioned method in order to improve a pass-through-flux on a Co—Fe—Zr based alloy target, but could not reduce the magnetic permeability sufficiently and could not obtain a strong pass-through-flux.

Therefore, the present inventors further investigated and consequently found the following: Co, a ferromagnetic material in itself, is used in the form of pure Co powder without alloying therewith Zr or the like, an element which constitutes a target material, while Fe is used in the form of alloy powder obtained by alloying of the other elements which constitute the target material, and a structure is formed by mixing the pure Co powder and the alloy powder and sintering the mixture, whereby there is obtained a target having a very low magnetic permeability which has been unattainable. Thus, the present invention has been accomplished.

In the present invention, a target having a low magnetic permeability is obtained by adopting a method utterly different from the above-mentioned conventional method. The reason for such reduction of the magnetic permeability is presumed as follows.

The following is known: in general, magnetic moment and magnetic anisotropy greatly affect the magnetic permeability of polycrystals, and a high magnetic permeability is attained at a large magnetic moment and a low magnetic anisotropy, while a low magnetic permeability is attained at a small magnetic moment and a high magnetic anisotropy.

On the other hand, as to the crystal structure of an alloy phase containing Co and Fe, there are HCP (hexagonal close-packed lattice, FCC (face-centered cubic lattice) and BCC (body-centered cubic lattice). Of these, HCP phase has the highest crystal magnetic anisotropy. It is known that pure Co has a crystal structure critical temperature of about 422° C. and has HCP below the critical temperature and FCC above the critical temperature. When Co is alloyed by addition of another element, FCC or BCC, which has a low crystal magnetic anisotropy, is formed in some cases even in room temperature.

The following is conjectured: in the present invention, magnetic anisotropy is enhanced by making Co present as a HCP-Co phase in the microstructure of a Co—Fe—Zr based alloy target material without alloying with another element which constitutes the target material, and moreover, the magnetic moment of the whole target material is reduced by making Fe present as an alloy phase with another element, whereby a low magnetic permeability and a strong pass-through-flux could be attained by the synergistic effect of the enhancement of the magnetic anisotropy and the reduction of the magnetic moment.

In the present invention, the term “phase composed of HCP-Co” means a phase in which a portion other than unavoidable impurities and the surrounding diffusion layer is composed of Co and whose crystal structure is composed of HCP. The crystal structure of the HCP-Co phase can be judged, for example, by an X-ray diffraction method.

In the present invention, the term “alloy phase composed mainly of Fe” means an alloy phase consisting of 50% or more (atomic ratio) of Fe, Zr and the element(s) M, or an alloy phase consisting of 50% or more (atomic ratio) of Fe, Zr, the element(s) M and Co.

In the microstructure of the Co—Fe—Zr based alloy target material of the present invention, the ratio between the HCP-Co phase and the alloy phase composed mainly of Fe varies depending on the chemical composition of the target material.

For example, when the Co content is low, a structure is formed in which the phase composed of HCP-Co and the alloy phase composed mainly of Fe are dispersed. When the Co content is high, a structure is formed in which the alloy phase composed mainly of Fe is dispersed in the main phase composed of HCP-Co. Needless to say, the effects described above can be obtained in either case.

The phase composed of HCP-Co and the alloy phase composed mainly of Fe are different in sputtering rate in some cases. When a coarse portion is present, a problem such as abnormal discharge or particles is caused in some cases during film deposition by sputtering. Therefore, stable sputtering becomes possible when each of the phases is finely dispersed. Accordingly, it is preferable to adjust the average grain size of each of the alloy phase composed mainly of Fe and the phase composed of HCP-Co to 200 μm or less.

As to the chemical composition of the sputtering target material of the present invention, its compositional formula based on the atomic ratio is represented by (Coₓ—Fe_{100-X})_{100-(Y+Z)}—Zr_{Y}-M_{Z} (20≦X≦70, 2≦Y≦15 and 2≦Z≦10) in which the element(s) M is one or more elements selected from the group consisting of Ti, V, Nb, Ta, Cr, Mo, W, Si, Al and Mg.

The reason why the compositional ratio X between Co and Fe is in the range 20≦X≦70 is that a thin film having a high saturation magnetization and excellent soft magnetic characteristics can be formed by adjusting the Co content of a Co—Fe binary alloy film to 20 to 70% by atom.

The reason why the adding amount Y of Zr is in the range 2≦Y≦15 is that a thin film of amorphous phase having excellent soft magnetic characteristics can be formed by adding Zr in the above range. The reason for employing the above range is as follows: when the amount of Zr added is less than 2% by atom, the thin film is crystallized, so that it is difficult to attain excellent soft magnetic characteristics; and when the amount of Zr added is more than 15% by atom, the saturation magnetization is lowered. For attaining a higher saturation magnetization, it is more preferable to adjust the adding amount Y of Zr to an amount in the range 2≦Y≦8.

The reason why the adding amount Z of the one or more elements selected from the elements M (Ti, V, Nb, Ta, Cr, Mo, W, Si, Al and Mg) is in the range 2≦Z≦10 is that the addition of the one or more elements selected from the elements M in the above range is effective in reducing the magnetostriction of a thin film to improve its soft magnetic characteristics and in improving the corrosion resistance. Of the elements M, Nb and Ta are elements particularly effective in reducing the magnetostriction of the thin film to improve the soft magnetic characteristics. In addition, Ti, V, Cr, Mo, W, Si, Al and Mg are elements particularly effective in improving the corrosion resistance of the thin film.

The above-mentioned target material of the present invention can be obtained by sintering under pressure mixed powder obtained by mixing Co powder and alloy powder obtained by subjecting Fe, Zr and the element(s) M to alloying treatment, so that the composition of the mixed powder may be adjusted to a predetermined composition. Although the Co powder has HCP in room temperature as described above, it has FCC or BCC in some cases when its alloying with Fe, Zr and the element(s) M proceeds. Therefore, it is important to leave a Co phase as HCP in the structure of the target material after sintering by mixing pure Co powder as it is with the other elements and sintering the resulting mixture under pressure. Similarly, an alloy phase composed mainly of Fe can be efficiently made present in the structure of the target material after sintering by sintering under pressure alloy powder obtained by subjecting Fe, Zr and the element(s) M to alloying treatment.

When the liquid phase temperature of an alloy composed of Fe, Zr and the element(s) M is so high that the production of powder of the alloy is difficult, alloy powder obtained by incorporating a portion of Co and subjecting Fe, Co, Zr and the element(s) M to alloying treatment may also be used. This is because the liquid phase temperature is lowered by the incorporation of Co into the alloy powder.

Even in this case, the Co content of the alloy powder is about 10% by atom based on the atoms in the whole target.

As a method for sintering the mixed powder under pressure, methods such as hot pressing, hot isostatic pressing, spark sintering, hot extrusion and the like can be adopted. Of these, hot isostatic pressing is especially preferable because it permits application of a high pressure, so that a dense sintered product can be obtained even if the formation of a diffusion layer is suppressed by keeping the maximum temperature low.

The maximum temperature at the sintering under pressure is preferably set at a temperature of not higher than 1200° C. and not lower than 800° C. The reason is as follows: when the sintering temperature is lower than 800° C., it is difficult to obtain a dense sintered product; and when the sintering temperature is higher than 1200° C., the alloy powder is melted during the sintering in some cases. In addition, when the maximum temperature is too high, the diffusion of the powders mixed into each other proceeds excessively, so that it becomes difficult to leave a HCP-Co phase sufficiently. Therefore, the maximum temperature is more preferably set in the range of 900° C. to 1100° C.

The maximum pressure at the sintering under pressure is preferably set at 20 MPa or more. The reason is that when the maximum pressure is less than 20 MPa, no dense sintered product can be obtained.

As the alloying treatment in the present invention, rapid solidification treatment is preferably employed which makes it possible to obtain a fine structure. Like the alloy powder, the Co powder is also preferably produced by employing the rapid solidification treatment in order to obtain fine powder. As a method for the rapid solidification treatment, a gas atomization method is preferable which makes it possible to obtain spherical powder that is contaminated with only a small amount of impurities, has a high packing density and is suitable for sintering. For suppressing oxidation, an inert gas such as argon gas or nitrogen gas is preferably used as atomization gas.

### EXAMPLE 1

The present invention is explained in further detail with the following working example.

In the following working example, the following composition of alloy was employed in all cases: Co-27.6Fe-4Zr-4Nb (% by atom). After each of the powders listed in Table 1 was produced by a gas atomization method using Ar gas, all the atomized powders obtained were sieved through a 60-mesh wire screen. The atomized powders were weighed and then mixed in each combination shown in Table 1 so that the composition of the resulting mixed powder might be Co-27.6Fe-4Zr-4Nb (% by atom). The mixed powder was packed into a capsule made of soft steel, and was degassed, after which the capsule was sealed. Then, a sintered product is produced by hot isostatic pressing under the following conditions: pressure 122 MPa, temperature 950° C., and holding time 1 hour. The sintered product was machined into a Co—Fe—Zr based alloy target material with a diameter of 190 mm and a thickness of 12 mm.

An ingot having the same composition as above was produced by melt casting and machined into a Co—Fe—Zr based alloy target material with a diameter of 190 mm and a thickness of 12 mm.

TABLE 1

| Sample | Composition and combination | |
|---|---|---|
| No. | of starting powders | Note |
| 1 | Co, Fe—11.2Zr—11.2Nb | Example 1 of |
| | (% by atom) | present invention |
| 2 | Co—5Zr—4Nb (% by atom), | Comparative |
| | Fe—1.6Zr—4Nb (% by atom) | example 1 |
| 3 | Co—5.9Zr (% by atom), | Comparative |
| | Fe—12.7Nb (% by atom) | example 2 |
| 4 | Co—27.6Fe—4Zr—4Nb (% by | Comparative |
| | atom) Melt-cast material | example 3 |

Two 10 mm×10 mm test pieces were cut out of the end of the target material as each of the above-mentioned sample 1 and sample 4 and buffed. Then, one of the test pieces was subjected to ion milling using Ar gas, followed by observation of the microstructure by the use of a scanning electron microscope. The other test piece was subjected to phase identification by X-ray diffraction measurement. The X-ray diffraction measurement was carried out with an X-ray diffraction apparatus RINT2500V manufactured by Rigaku Corporation, by using Co as a radiation source.

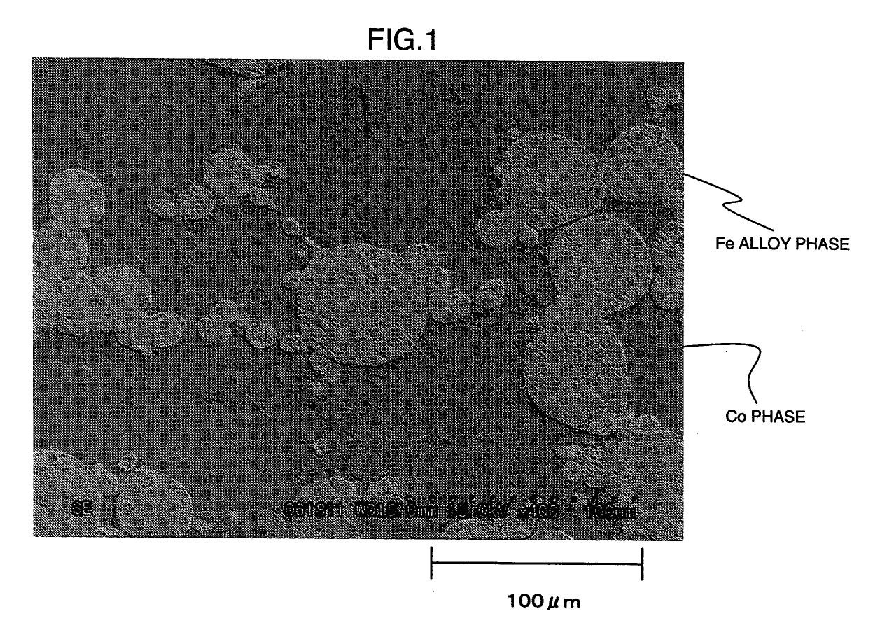

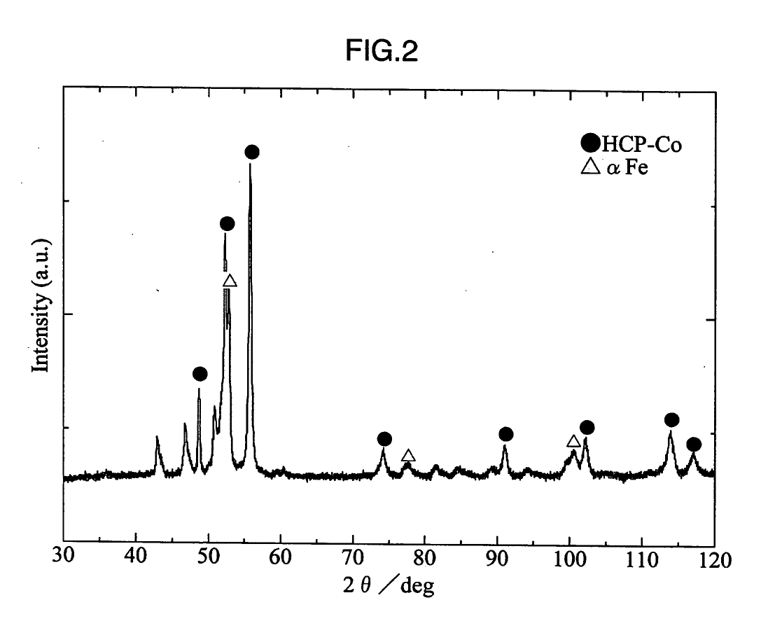

FIG. 1 shows a scanning electron micrograph of the microstructure of sample 1. FIG. 2 shows an X-ray diffraction pattern of sample 1. It can be seen from FIG. 1 that the microstructure of sample 1 (example 1 of the invention) is composed of a light-gray Co phase and a white Fe alloy phase. In addition, as can be seen from FIG. 2, the X-ray diffraction pattern of sample 1 (example 1 of the invention) shows peaks reflecting a HCP-Co phase, an αFe phase and a phase composed substantially of a Fe₂Zr intermetallic compound, respectively. Therefore, the following identification can be made: the Co phase in the microstructure is the HCP-Co phase and the Fe alloy phase in the microstructure is composed of the αFe phase and the intermetallic compound phase.

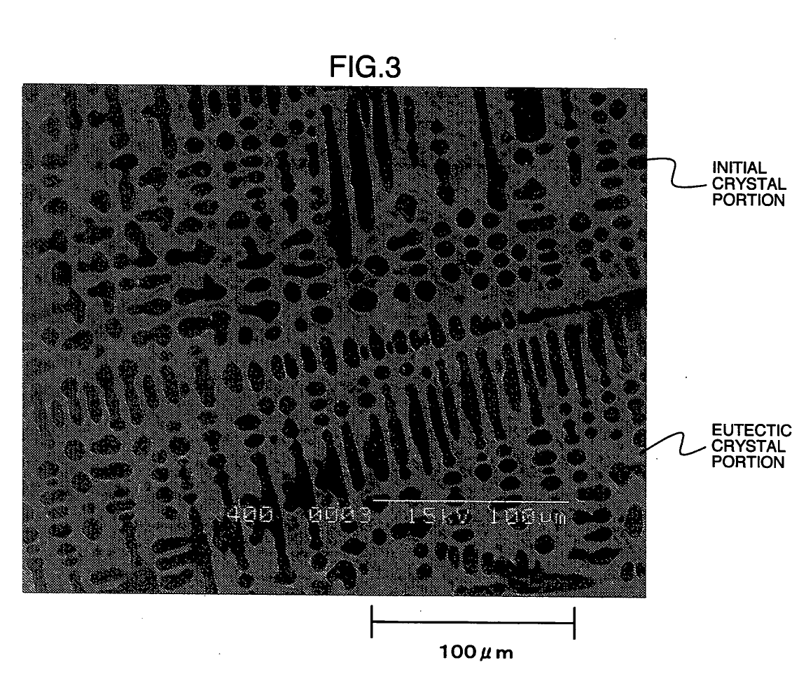

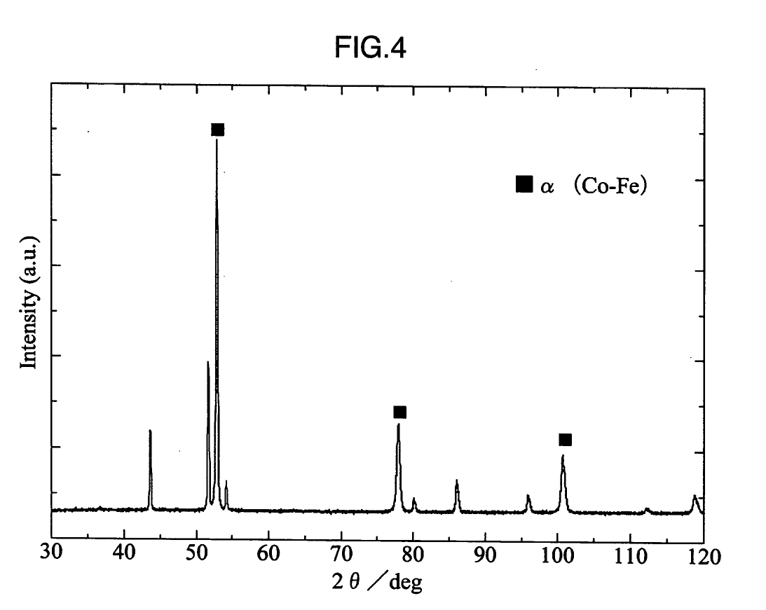

FIG. 3 shows a scanning electron micrograph of the microstructure of sample 4. FIG. 4 shows an X-ray diffraction pattern of sample 4. It can be seen from FIG. 3 that the microstructure of sample 4 (comparative example 3) is a typical melt-cast structure and is composed of a dark-gray initial crystal portion and a light-gray eutectic crystal portion. In addition, the X-ray diffraction pattern of sample 4 (comparative example 3) shown in FIG. 4 shows peaks reflecting an α(Co—Fe) phase and a phase composed substantially of a Co₂Nb intermetallic compound, respectively. Therefore, the following identification can be made: the initial crystal portion of the microstructure is the α(Co—Fe) phase and the eutectic crystal portion in the microstructure is composed of the α(Co—Fe) phase and the intermetallic compound phase. In this case, α(Co—Fe) is a solid solution composed mainly of Co and Fe and is a phase having a BCC structure.

Then, a test piece with a length of 30 mm, a width of 10 mm and a thickness of 5 mm was cut out of the end of each target material produced. A magnetization curve of each of the test pieces obtained was measured with a direct-current magnetic characteristics measuring apparatus TRF5A manufactured by Toei Industry Co., Ltd. The maximum magnetic permeability was determined from the magnetization curve obtained and is shown in Table 2. It can be seen from Table 2 that the target material as sample 1 (an example of the invention) has the lowest maximum magnetic permeability.

TABLE 2

| | Maximum magnetic | |
|---|---|---|
| Sample No. | permeability | Note |
| 1 | 36.2 | Example 1 of present |
| | | invention |
| 2 | 50.6 | Comparative example 1 |
| 3 | 43.4 | Comparative example 2 |
| 4 | 42.0 | Comparative example 3 |

Next, a pass-through-flux (hereinafter referred to as PTF) on each target material produced was measured and is shown in Table 3. The PTF measurement was carried out by a method in which a permanent magnet was set on the back of the target material and a magnetic flux passed through onto the surface of the target material was measured. This method permits quantitative measurement of a pass-through-flux in a state similar to that in a magnetron sputtering apparatus. The actual measurement was carried out on the basis of ASTM F1761-00 (Standard Test Method for Pass Through Flux of Circular Magnetic Sputtering Targets), and PTF was calculated by the following equation:

(PTF)=100×(intensity of magnetic flux in the presence of target material)/(intensity of magnetic flux in the absence of target material) (%)

TABLE 3

| Sample No. | Thickness (mm) | PTF (%) | Note |
|---|---|---|---|
| 1 | 12 | 19.5 | Example 1 of |
| | | | present invention |
| 2 | 5 | 20.0 | Comparative |
| | | | example 1 |
| 3 | 12 | 13.5 | Comparative |
| | | | example 2 |

As can be seen from Table 3 showing the result of the PTF measurement, PTF on sample 1 (an example of the invention) is substantially equal to that on sample 2 (comparative example 1) having a small thickness and has a value higher than the PTF value on sample 3 (comparative example 2) having the same thickness (12 mm) as that of sample 1. This result agrees with the above-mentioned result of measuring the maximum magnetic permeability and indicates that a very strong pass-through-flux can be obtained even if the thickness is set at a large thickness.

It could be confirmed by the above that the Co—Fe—Zr based alloy target material of the present invention composed of the microstructure, in which the phase composed of HCP-Co and the alloy phase composed mainly of Fe are finely dispersed, has a much lower magnetic permeability than do the target materials produced by other production processes and gives a strong pass-through-flux.

### EXAMPLE 2

In the following working example, the following composition of alloy was employed in all cases: Co-27Fe-5Zr-5Ta (% by atom). Except for using each combination of the powders listed in Table 4, Co—Fe—Zr based alloy target materials with a diameter of 190 mm and a thickness of 15 mm were obtained by the same process as in Example 1. In addition, an ingot having the same composition as above was produced by melt casting and machined into a Co—Fe—Zr based alloy target material with a diameter of 190 mm and a thickness of 15 mm.

TABLE 4

| Sample | Composition and combination | |
|---|---|---|
| No. | of starting powders | Note |
| 11 | Co, Fe—15.91Co—11.36Zr—11.36Ta | Example 2 of |
| | (% by atom) | present invention |
| 12 | Co—27Fe—5Zr—5Ta (% by atom) | Comparative |
| | | example 4 |
| 13 | Co—27Fe—5Zr—5Ta (% by atom) | Comparative |
| | Melt-cast material | example 5 |

Test pieces were cut out of end of the target material as the above-mentioned sample 11 in the same manner as in Example 1 and subjected to microstructure observation using a scanning electron microscope and phase identification by X-ray diffraction measurement. Each of the above-mentioned microstructure observation and X-ray diffraction measurement was carried out by the same method and with the same apparatus as in Example 1.

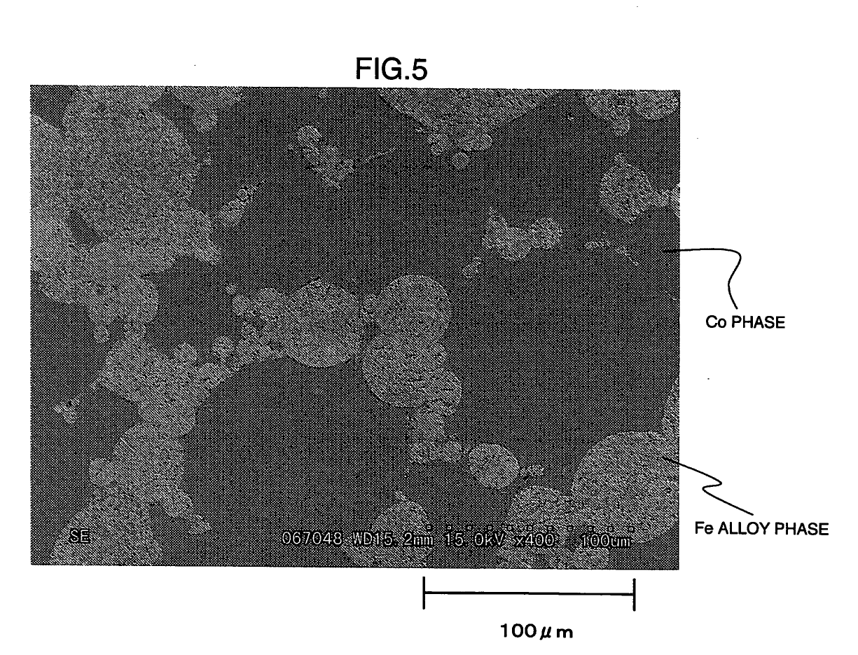

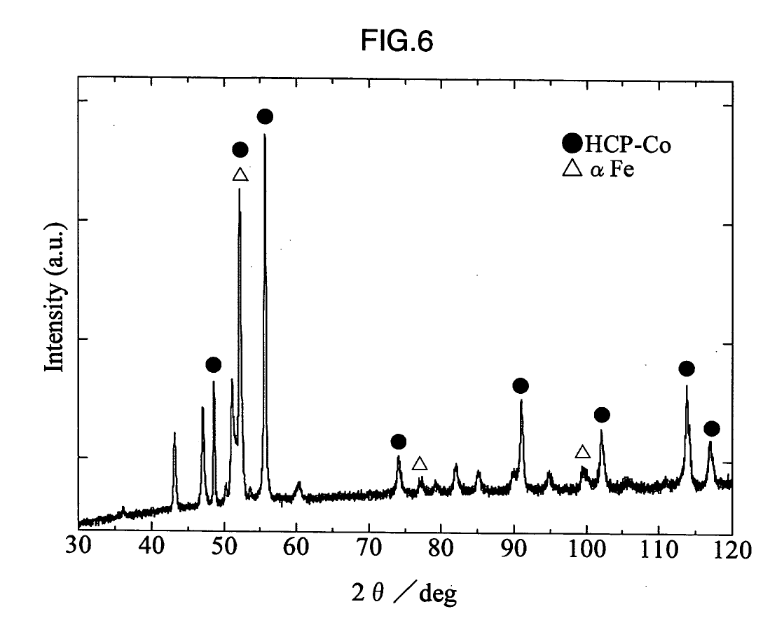

FIG. 5 shows a scanning electron micrograph of the microstructure of sample 11. FIG. 6 shows an X-ray diffraction pattern of sample 11. It can be seen from FIG. 5 that the microstructure of sample 11 (example 2 of the invention) is composed of a light-gray Co phase and a white Fe alloy phase. In addition, as can be seen from FIG. 6, the X-ray diffraction pattern of sample 11 (example 2 of the invention) shows peaks reflecting a HCP-Co phase, an αFe phase and a phase composed substantially of a Fe₂Zr intermetallic compound, respectively. Therefore, the following identification can be made: the Co phase in the microstructure is the HCP-Co phase and the Fe alloy phase in the microstructure is composed of the αFe phase and the intermetallic compound phase.

Then, a test piece was cut out of the end of each target material produced and a magnetization curve of the test piece was measured by the same method as in Example 1, after which the maximum magnetic permeability was determined from the magnetization curve obtained. In addition, PTF on each target material produced was also measured by the same method as in Example 1. Table 5 shows the maximum permeability measured and Table 6 the PTF value measured.

TABLE 5

| | Maximum magnetic | |
|---|---|---|
| Sample No. | permeability | Note |
| 11 | 34.0 | Example 2 of present |
| | | invention |
| 12 | 38.4 | Comparative example 4 |
| 13 | 39.5 | Comparative example 5 |

TABLE 6

| Sample No. | Thickness (mm) | PTF (%) | Note |
|---|---|---|---|
| 11 | 15 | 20.7 | Example 2 of |
| | | | present invention |
| 12 | 15 | 17.8 | Comparative |
| | | | example 4 |
| 13 | 15 | 17.7 | Comparative |
| | | | example 5 |

From Table 5 and Table 6, it can be seen that the target material as sample 11 having the microstructure, in which the phase composed of HCP-Co and the alloy phase composed mainly of Fe are finely dispersed, has the lowest maximum magnetic permeability. In addition, PTF on sample 11 has the highest value and this result agrees with the result of measuring the maximum magnetic permeability and indicates that a very strong pass-through-flux can be obtained.

### EXAMPLE 3

In the following working example, the following composition of alloy was employed in all cases: Co-36.8Fe-5Zr-3Ta (% by atom). Except for using each combination of the powders listed in Table 7, Co—Fe—Zr based alloy target materials with a diameter of 190 mm and a thickness of 15 mm were obtained by the same process as in Example 1. In addition, an ingot having the same composition as above was produced by melt casting and machined into a Co—Fe—Zr based alloy target material with a diameter of 190 mm and a thickness of 15 mm.

TABLE 7

| Sample | Composition and combination | |
|---|---|---|
| No. | of starting powders | Note |
| 21 | Co, Fe—18.25Co—9.12Zr—5.47Ta | Example 3 of |
| | (% by atom) | present |
| | | invention |
| 22 | Co—36.8Fe—5Zr—3Ta | Comparative |
| | (% by atom) | example 6 |
| 23 | Co—36.8Fe—5Zr—3Ta (% by atom) | Comparative |
| | Melt-cast material | example 7 |

Test pieces were cut out of the end of the target material as the above-mentioned sample 21 in the same manner as in Example 1 and subjected to microstructure observation using a scanning electron microscope and phase identification by X-ray diffraction measurement. Each of the above-mentioned microstructure observation and X-ray diffraction measurement was carried out by the same method and with the same apparatus as in Example 1.

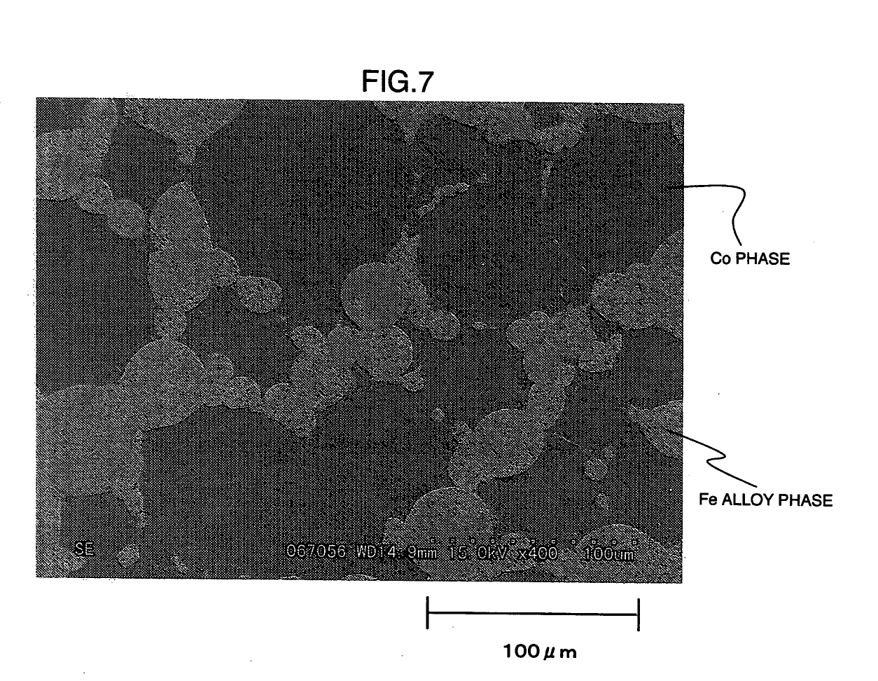

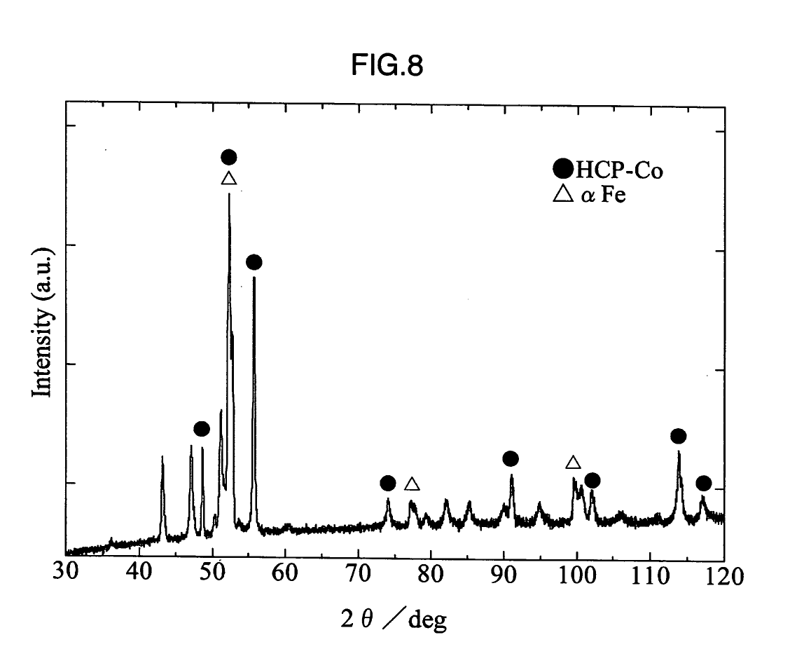

FIG. 7 shows a scanning electron micrograph of the microstructure of sample 21. FIG. 8 shows an X-ray diffraction pattern of sample 21. It can be seen from FIG. 7 that the microstructure of sample 21 (example 3 of the invention) is composed of a light-gray Co phase and a white Fe alloy phase. In addition, as can be seen from FIG. 8, the X-ray diffraction pattern of sample 21 (example 3 of the invention) shows peaks reflecting a HCP-Co phase, an αFe phase and a phase composed substantially of a Fe₂Zr intermetallic compound, respectively. Therefore, the following identification can be made: the Co phase in the microstructure is the HCP-Co phase and the Fe alloy phase in the microstructure is composed of the αFe phase and the intermetallic compound phase.

Then, a test piece was cut out of the end of each target material produced and a magnetization curve of the test piece was measured by the same method as in Example 1, after which the maximum magnetic permeability was determined from the magnetization curve obtained. In addition, PTF on each target material produced was also measured by the same method as in Example 1. Table 8 shows the maximum permeability measured and Table 9 the PTF value measured.

TABLE 8

| | Maximum magnetic | |
|---|---|---|
| Sample No. | permeability | Note |
| 21 | 43.6 | Example 3 of present |
| | | invention |
| 22 | 66.3 | Comparative example 6 |
| 23 | 90.0 | Comparative example 7 |

TABLE 9

| Sample No. | Thickness (mm) | PTF (%) | Note |
|---|---|---|---|
| 21 | 15 | 17.9 | Example 3 of |
| | | | present invention |
| 22 | 15 | 14.8 | Comparative |
| | | | example 6 |

From Table 8 and Table 9, it can be seen that the target material as sample 21 having the microstructure, in which the phase composed of HCP-Co and the alloy phase composed mainly of Fe are finely dispersed, has the lowest maximum magnetic permeability. In addition, PTF on sample 21 has a relatively high value and this result agrees with the result of measuring the maximum magnetic permeability and indicates that a very strong pass-through-flux can be obtained.

### EXAMPLE 4

In the following working example, the following composition of alloy was employed in all cases: Fe-27.6Co-5Zr-3Ta (% by atom). Except for using each combination of the powders listed in Table 10 and for using Co powder obtained by melt stamping or crushing Co—Fe—Zr based alloy target materials with a diameter of 190 mm and a thickness of 15 mm were obtained by the same process as in Example 1. In addition, an ingot having the same composition as above was produced by melt casting and machined into a Co—Fe—Zr based alloy target material with a diameter of 190 mm and a thickness of 15 mm.

TABLE 10

| Sample | Composition and combination | |
|---|---|---|
| No. | of starting powders | Note |
| 31 | Co, Fe—6.91Zr—4.14Ta | Example 4 of |
| | (% by atom) | present invention |
| 32 | Fe—27.6Co—5Zr—3Ta | Comparative |
| | (% by atom) | example 8 |
| 33 | Fe—27.6Co—5Zr—3Ta (% by | Comparative |
| | atom) Melt-cast material | example 9 |

Test pieces were cut out of the end of the target material as each of the above-mentioned samples 31 and 33 in the same manner as in Example 1 and subjected to microstructure observation using a scanning electron microscope and phase identification by X-ray diffraction measurement. Each of the above-mentioned microstructure observation and X-ray diffraction measurement was carried out by the same method and with the same apparatus as in Example 1.

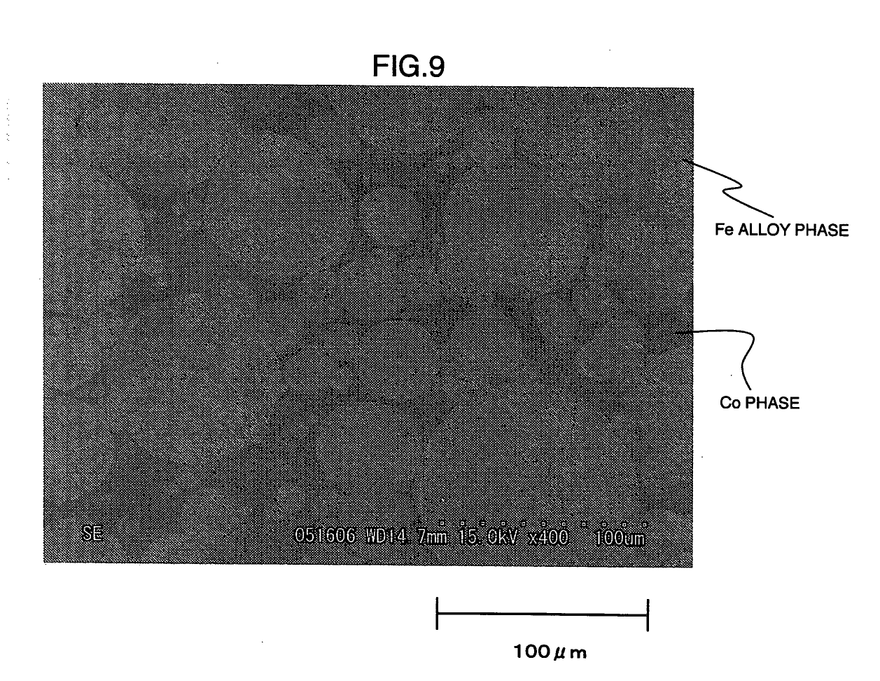

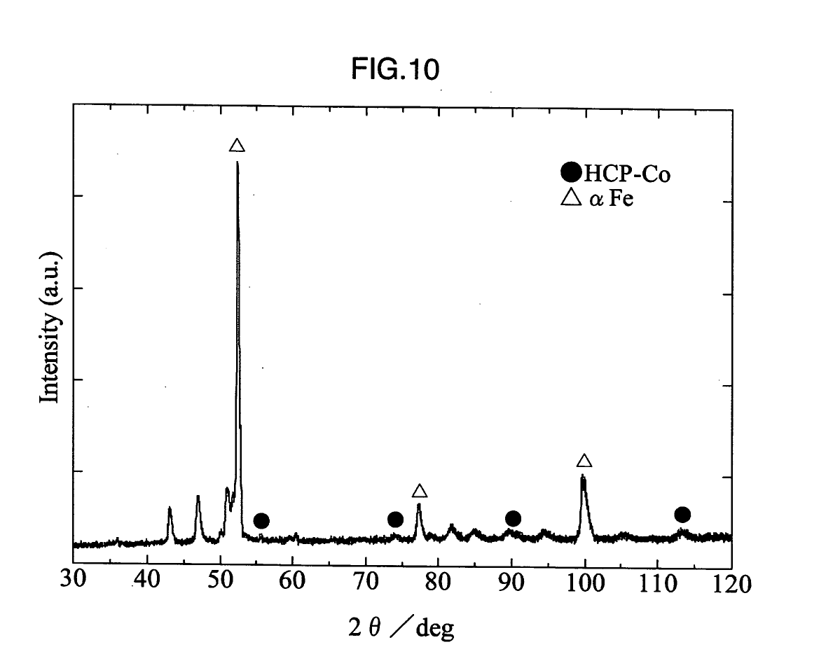

FIG. 9 shows a scanning electron micrograph of the microstructure of sample 31. FIG. 10 shows an X-ray diffraction pattern of sample 31. It can be seen from FIG. 9 that the microstructure of sample 31 (example 4 of the invention) is composed of a light-gray Co phase and a white Fe alloy phase. In addition, it was confirmed by FIG. 10 that the X-ray diffraction pattern of sample 31 (example 4 of the invention) showed peaks reflecting a HCP-Co phase, an αFe phase and a phase composed substantially of a Fe₂Zr intermetallic compound, respectively. Moreover, the presence of the Co phase was confirmed by the analysis of the test piece with an X-ray micro-analyzer (EPMA: Electron Probe Micro-Analyzer). Therefore, the following identification can be made: the Co phase in the microstructure is the HCP-Co phase and the Fe alloy phase in the microstructure is composed of the αFe phase and the intermetallic compound phases.

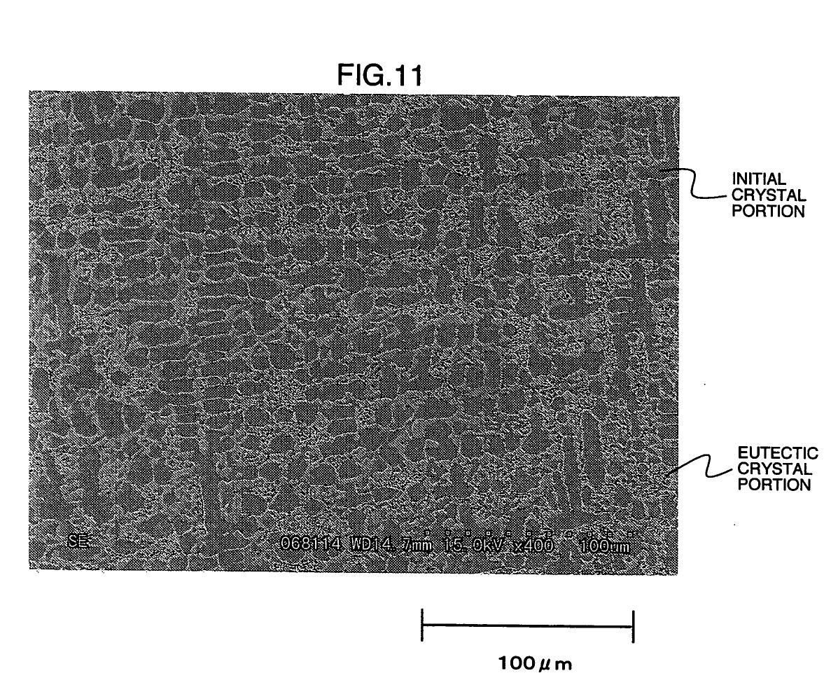

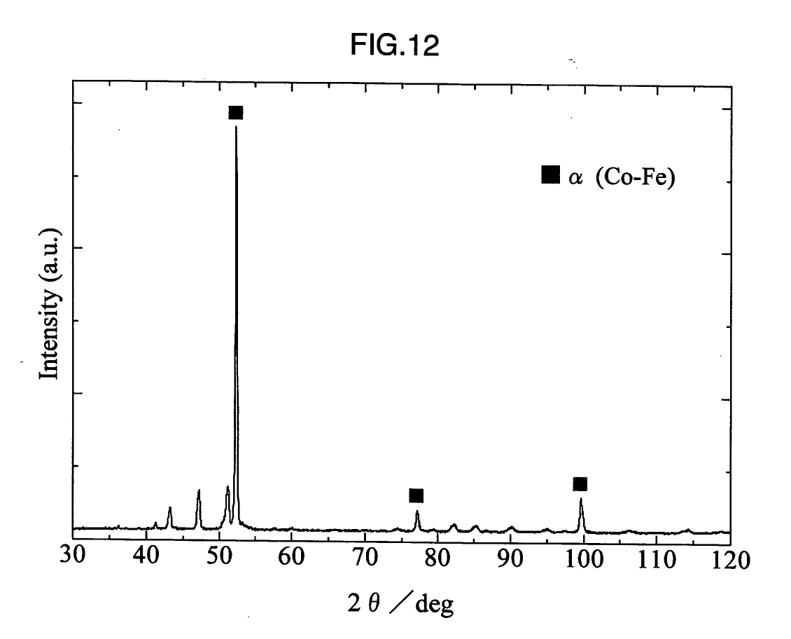

FIG. 11 shows a scanning electron micrograph of the microstructure of sample 33. FIG. 12 shows an X-ray diffraction pattern of sample 33. It can be seen from FIG. 11 that the microstructure of sample 33 (comparative example 9) is a typical melt-cast structure and is composed of a light-gray initial crystal portion and a white eutectic crystal portion. In addition, the X-ray diffraction pattern of sample 33 (comparative example 9) shown in FIG. 12 shows peaks reflecting an α(Co—Fe) phase and a phase composed substantially of a Fe₂Zr intermetallic compound, respectively. Therefore, the following identification can be made: the initial crystal portion of the microstructure is the α(Co—Fe) phase and the eutectic crystal portion of the microstructure is composed of the α(Co—Fe) phase and the intermetallic compound phase.

Then, a test piece was cut out of the end of each target material produced and a magnetization curve of the test piece was measured by the same method as in Example 1, after which the maximum magnetic permeability was determined from the magnetization curve obtained. In addition, PTF on each target material produced was also measured by the same method as in Example 1. Table 11 shows the maximum permeability measured and Table 12 the PTF value measured.

TABLE 11

| | Maximum magnetic | |
|---|---|---|
| Sample No. | permeability | Note |
| 31 | 84.6 | Example 4 of present |
| | | invention |
| 32 | 137.5 | Comparative example 8 |
| 33 | 133.3 | Comparative example 9 |

TABLE 12

| Sample No. | Thickness (mm) | PTF (%) | Note |
|---|---|---|---|
| 31 | 15 | 9.6 | Example 4 of |
| | | | present invention |
| 32 | 15 | 8.1 | Comparative |
| | | | example 8 |

From Table 11 and Table 12, it can be seen that the target material as sample 31 having the microstructure, in which the phase composed of HCP-Co and the alloy phase composed mainly of Fe are finely dispersed, has the lowest maximum magnetic permeability. In addition, PTF on sample 31 has a relatively high value and this result agrees with the result of measuring the maximum magnetic permeability and indicates that a very strong pass-through-flux can be obtained.

In the present invention, as the microstructure of a Co—Fe—Zr based alloy target material, a structure is employed in which a phase consisting of HCP-Co and a phase consisting of an alloy composed mainly of Fe are dispersed, whereby a Co—Fe—Zr based alloy target material having a low magnetic permeability and capable of giving a strong pass-through-flux can be obtained. As a result, stable magnetron sputtering can be conducted in the deposition of a soft magnetic film.

1. A Co—Fe—Zr based alloy sputtering target material represented by the compositional formula based on the atomic ratio: (Coₓ—Fe_{100-X})_{100-(Y+Z)}—Zr_{Y}-M_{Z} (20≦X≦70, 2≦Y≦15 and 2≦Z≦10) in which the element(s) M is one or more elements selected from the group consisting of Ti, V, Nb, Ta, Cr, Mo, W, Si, Al and Mg, wherein a phase composed of HCP-Co and an alloy phase composed mainly of Fe are finely dispersed in the microstructure of the target material.

2. A Co—Fe—Zr based alloy sputtering target material represented by the compositional formula based on the atomic ratio: (Coₓ—Fe_{100-X})_{100-(Y+Z)}—Zr_{Y}-M_{Z} (20≦X≦70, 2≦Y≦15 and 2≦Z≦10) in which the element(s) M is one or more elements selected from the group consisting of Ti, V, Nb, Ta, Cr, Mo, W, Si, Al and Mg, wherein an alloy phase composed mainly of Fe is finely dispersed in a main phase composed of HCP-Co in the microstructure of the target material.

3. A Co—Fe—Zr based alloy sputtering target material according to claim 1, wherein said phase composed of HCP-Co and said alloy phase composed mainly of Fe have an average grain size of 200 μm or less.

4. A Co—Fe—Zr based alloy sputtering target material according to claim 2, wherein said phase composed of HCP-Co and said alloy phase composed mainly of Fe have an average grain size of 200 μm or less.

5. A process for producing a Co—Fe—Zr based alloy sputtering target material according to claim 1, which comprises sintering under pressure mixed powder obtained by mixing Co powder and alloy powder obtained by subjecting Fe, Zr and the element(s) M to alloying treatment.

6. A process for producing a Co—Fe—Zr based alloy sputtering target material according to claim 2, which comprises sintering under pressure mixed powder obtained by mixing Co powder and alloy powder obtained by subjecting Fe, Zr and the element(s) M to alloying treatment.

7. A process for producing a Co—Fe—Zr based alloy sputtering target material according to claim 1, which comprises sintering under pressure mixed powder obtained by mixing Co powder and alloy powder obtained by subjecting Fe, Co, Zr and the element(s) M to alloying treatment.

8. A process for producing a Co—Fe—Zr based alloy sputtering target material according to claim 2, which comprises sintering under pressure mixed powder obtained by mixing Co powder and alloy powder obtained by subjecting Fe, Co, Zr and the element(s) M to alloying treatment.

9. A process for producing a Co—Fe—Zr based alloy sputtering target material according to claim 5, wherein said alloying treatment is rapid solidification treatment of an alloy melt.

10. A process for producing a Co—Fe—Zr based alloy sputtering target material according to claim 7, wherein said alloying treatment is rapid solidification treatment of an alloy melt.
